(19) United States
(12) Patent Application Publication
(10) Pub. No.: US 2013/0032385 A1
(43) Pub. Date: Feb. 7, 2013

(54) METAL THIN SHIELD ON ELECTRICAL DEVICE

(71) Applicants: Peng Cheng Lin, San Jose, CA (US); Mario Francisco Velez, San Diego, CA (US)

(72) Inventors: Peng Cheng Lin, San Jose, CA (US); Mario Francisco Velez, San Diego, CA (US)

(73) Assignee: QUALCOMM MEMS Technologies, Inc., San Diego, CA (US)

(21) Appl. No.: 13/197,162

(22) Filed: Aug. 3, 2011

(51) Int. Cl. H05K 1/18; H05K 3/30

(52) U.S. Cl. 174/260; 29/841

(57) ABSTRACT

This disclosure provides systems and methods for forming a metal thin film shield over a thin film cap to protect electromechanical systems devices in a cavity beneath. In one aspect, a dual or multi layer thin film structure is used to seal a electromechanical device. For example, a metal thin film shield can be mated over an oxide thin film cap to encapsulate the electromechanical device and prevent degradation due to wafer thinning, dicing and package assembly induced stresses, thereby strengthening the survivability of the electromechanical device in the encapsulated cavity. During redistribution layer processing, a metal thin film shield, such as a copper layer, is formed over the wafer surface, patterned and metalized.

### TECHNICAL FIELD

This disclosure relates to a metal thin film shield on a electrical device, such as a microelectromechanical systems (MEMS) device. More specifically, the disclosure relates to use of a metal thin film to protect an oxide thin film encapsulation layer from damage or degradation.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, MEMS devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

MEMS devices contain fragile movable parts that are packaged in a clean and stable/inert environment. Encapsulation of the MEMS device is possible using proven certain ceramic or metal-can packages, but the package can be bulky and the cost can be high and can pose many technological complexities. For instance, standard wafer sawing is not typically used, as it may destroy the MEMS device. It follows that packaging is carried out during wafer processing, prior to die singulation (wafer dicing). This packaging step is referred to as wafer-level packaging. For individual devices with a thin profile, wafer backgrinding may be required. More often than not, MEMS devices can be damaged during tape lamination, backgrinding, and subsequent tape demounting. Thus, backgrinding and sawing are done after wafer-level packaging for these thin profile devices. The wafer-level packaging creates an on-wafer device scale enclosure around, or sealed cavity for, the MEMS device, and serves as a first protective interface. Once the device is sealed at the wafer level, the MEMS product wafers can be diced without great danger of breaking the MEMS device. In addition to a low-cost fabrication process and physical protection, the wafer-level package should be strong, equipped with electrical RF signal feed-throughs and be near hermetic, preventing any particles and moisture from migrating into the region under the freely moving MEMS.

Unfortunately, MEMS devices are sensitive to environmental conditions such as humidity, as well as physical conditions related to manufacturing and packing. MEMS packages contain often-fragile mechanical structures which should be protected and also provide an interface to the next level of components in the packaging hierarchy. However, in order to achieve affordable mass-produced devices, such devices should be fabricated in a cost effective manner.

### SUMMARY

The systems, methods and devices of the disclosure each have several innovative aspects, no single one of which is solely responsible for the desirable attributes disclosed herein.

One implementation is an electronic package, which includes a substrate having an electronic device. A thin-film cap can be sealed to the substrate to form a package, and the electronic device is inside the package. Further, a metal thin film layer can be deposited adjacent to the thin-film cap. The metal thin film can include one or more layers of copper. In one implementation, the metal thin film can reduce the likelihood of flexure of the thin-film cap. The metal thin film can be of a sufficient thickness to reduce the likelihood of the thin-film cap from being deformed during manufacturing. The metal thin film layer cap can extend to an underbump metal pad. The metal thin film can be a ground plane.

In one implementation, the device package further includes an additional metal thin film deposited over the metal thin film layer. The electronic device can comprise a varactor, an accelerometer, or a MEMS device array. In one implementation, the metal thin film provides a hermetic barrier.

Another implementation includes a method of manufacturing an electronic device. The method can provide a substrate having an electronic device and encapsulated by a thin-film cap. The method may further includes application of a metal thin film over the thin-film cap. In one implementation, the metal thin film is applied during a redistribution layer process. The metal thin film can be copper. The metal thin film can be passive. In one implementation, the method can further include applying an additional metal thin film. In one implementation, the electronic device can be a varactor.

In one implementation, the method further includes providing a passivation layer over the thin film cap before applying the metal thin film. Yet in another implementation, an electronic device package is provided, which includes a substrate having an electromechanical device, a thin film cap deposited above the electromechanical device and configured to encapsulate the electronic device into the package, and means for reinforcing the thin film cap with metal.

The electromechanical device can include a varactor, an accelerometer, or other MEMS device. The reinforcing means can have at least one metal thin film formed over the thin film cap. The at least one metal thin film can extend to an underbump metal pad. In one implementation, the means for reinforcing includes one or more layers of copper. In one implementation, the metal thin film layer is made from a thermally conductive material. This may allow the metal thin film layer to transfer heat from a higher temperature region to a lower temperature region.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows an example of a top view of an implementation of a packaged MEMS varactor device.

FIG. 1B is a cross-sectional view of the varactor device of FIG. 1A taken along line A-A.

FIG. 2 is an exemplary flow chart for an implementation of a method for forming a varactor.

FIG. 3 is a line graph showing an example of test data depicting the deflection of the TF-cap at certain pressures exerted during the molding process.

FIG. 4A is an electron micrograph image showing varactor devices after backgrinding and standard tape removal.

FIG. 4B is an electron micrograph image showing varactor devices after backgrinding and UV tape removal.

FIG. 5 is a top view of an integrated circuit metal thin film shields for wafer level chip scale packaging (WLCSP).

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in or associated with a variety of electronic devices such as, but not limited to, mobile telephones, multimedia Internet enabled cellular telephones, mobile television receivers, wireless devices, smart phones, Bluetooth devices, personal data assistants (PDAs), wireless electronic mail receivers, hand-held or portable computers, net books, notebooks, smart books, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, packaging (e.g., MEMS and non-MEMS), aesthetic structures (e.g., display of images on a piece of jewelry) and a variety of electromechanical systems devices. The teachings herein also can be used in applications such as, but not limited to, displays, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

One implementation is an electromechanical system device that is protected by a metal thin film shield. In one implementation, the metal thin film shield is between about 5 and 10 microns in thickness. The shield is configured to retain wafer-level packaging capability for manufacturing small package form factor MEMS devices. This metal thin film shield can be formed during a redistribution layer (RDL) process and may be deposited over a thin film cap (TF-cap) on the device. In one implementation, the device is a varactor. The TF-cap can be manufactured by oxide deposition, photo-resist (PR), litho, and etching. The TF-cap can be several microns thick, and used to enclose an open shell cavity to protect the MEMS device residing beneath the TF-cap. Under some circumstances, the TF-cap becomes vulnerable to induced stresses from molding pressures of about 700 to 1,200 psi. Thus, addition of a metal thin film shield adjacent to the TF-cap as described herein adds more protection from such stresses and may increase the rigidity of the TF-cap. Moreover, the addition of the metal thin film shield may protect the device from damage due to removal of tape after a wafer thinning or backgrinding process. To ensure no coupling capacitance is induced, the distance between the metal thin film and the electrode of the MEMS cannot be greater than a given dimension.

Coupling capacitance may be estimated by C=εₒεA/d, where εₒ is a constant and ε is a dielectric constant for materials of Polyimide, TF-cap, and Shell, A is the electro area, and d is the distance between two metal plates: electrode and metal thin film. In the current generation of MEMS devices, electrodes are an integral part of MEMS main structure. For example, if the distance between the electrode and the metal thin film (d) is 6 um, then the coupling capacitance (C) starts to diminish and thus, a distance (d) of 10 um would be recommended. As indicated in the above formula, modification of the electro area (A) may also be reduced to reduce C. To achieve this, cut outs at certain areas of metal thin film may be specified directly above the MEMS structure.

### Overview of Varactor Device

One example of a MEMS device, to which the described implementations may apply, is a varactor. Varactor diodes are semiconductor devices that behave like variable capacitors. When reverse-biased, they have a capacitance that varies with an applied voltage. They are often used in devices that require electronic tuning, such as radio devices.

Varactor diodes are commonly found in communication equipment on which electronic tuning is applied. They are an important component of radio frequency or RF applications. In addition to being referred to as varicaps, varactors are also known as voltage-variable capacitors and tuning diodes. Their symbol is that of a diode placed directly next to a capacitor.

In appearance, they may look like capacitors or regular diodes. The capacitance of a varactor decreases when the reverse-voltage gets larger. They are usually placed in parallel with an inductor to form a resonant frequency circuit. When the reverse voltage changes, so does the resonant frequency, which is why varactors may be substituted for mechanically tuned capacitors.

Such devices may use cantilever beams that are anchored or fixed at one or multiple ends allowing for suspension freely in a cavity or actuation via electrical pulses by control circuits with firmware instructions per design when a DC voltage is applied. The cavity in which the MEMS device is housed is typically enclosed to protect the MEMS device from direct contact and unwanted environmental stresses. Implementations utilizing a cap with a cavity down, and also thin film caps (TF-cap), are two known methods commonly used to enclose an open cavity where MEMS structures reside. In the case of the cavity down cap, the cap is attached with a sealant on the device substrate to form an enclosed housing for the MEMS device. The cavity down cap's material is typically the same as the material of the device substrate.

However, it may be costly to fabricate a smaller cap size at a few millimeters long or wide and tough enough to achieve consistent cap-to-substrate alignment accuracy. In one implementation, a thin film cap (TF-cap) can be manufactured by oxide deposition, photoresist (PR), lithography, and etch in order for several microns thick of TF-cap to enclose an open shell cavity to protect the MEMS device beneath. The TF-cap becomes vulnerable under various package assembly induced stresses, such as molding pressure of about 700 to 1,200 psi, and an additional layer of protection, such as cavity down cap is often required to shield not only the TF-cap but also the MEMS device, from degradation. Moreover, as the TF-cap widens its coverage area for larger MEMS devices, its strength can be weakened further as demonstrated by analytical modeling. For a large coverage area, the TF-cap tends to sag and may be in contact with MEMS structures if the sagging becomes severe.

In one implementation, the electromechanical devices are encapsulated prior to addition of a metal thin film shield layer. Encapsulation can protect electromechanical devices from environmental hazards, such as moisture and mechanical shock, as described above.

### Wafer Level Packaging

It is advantageous to package MEMS devices at the wafer level. Conventional wafer-level chip scale packages (WLCSP) combine the chip scale package advantages of small size and ease of handling with an efficient production approach based on batch packaging at wafer level. The essence of this type of processing is that the packages are created directly on the wafer, before the wafers are sawn into individual die units, with or without wafer thinning. In creating the package, additional layers of material, e.g., the thin film cap, may be deposited over the active surface of the die. The resulting savings in size, weight and money have led to wide acceptance of wafer-level packaging, primarily for surface mountable or pin-grid array, or a new generation of small- to medium-size die with low input-output (I/O) requirements.

Wafer-level packaging with a protective cavity adds mechanical protection, beginning at the wafer level, for devices with fragile surface features, such as MEMS, optoelectronics and sensors. Some of these devices require a controlled atmosphere in the cavity, while others function best in a vacuum. Wafer-level packaging of vacuum cavities brings the cost advantage of simultaneously sealing an entire wafer of cavities in vacuum. This eliminates the manufacturing inefficiencies and the costs of individual “pump down and pinch off” for archaic metal or ceramic vacuum packages.

Since cavity wafer-level packaging devices, by their nature are generally precluded from adding layers over the active devices on the wafer surface, cavity packages are created either by bonding a second wafer with pre-formed cavities over the device wafer (wafer stacking) or by dicing the second wafer and bonding the individual cavity chips onto the device wafer (chip-on-wafer). Most of these types of devices can require non-hermetic, near-hermetic and hermetic sealing methods.

A direct approach to fabricating a wafer-level cavity package is to adhesive-bond a cover wafer that contains etched cavities on its surface over a wafer containing active devices. A near-hermetic cavity with cost, weight and performance advantages uses a substrate, cap and seal. The cavity package can draw upon well-established printed circuit board (PCB) technology for a multilayer base, integrating high-speed cavity feed-throughs into the substrate itself. The components and circuitry are protected by a cap, which forms the cavity.

Cap-type packaging allows a unique method of sealing the lid assembly. The cap may be laser-welded at the bond line, using an infrared (IR) laser to create the seal. In some implementations, the cap is made of a material that is transparent to IR, so the beam passes through the cap with little absorption. An IR-absorbent material may be added to the cap at the bond line, localizing heating to the immediate seal area. The welded seal is formed from the cap material.

One example of a high-volume production hermetic cavity wafer level packages are those for MEMS devices in RF systems. This wafer-level package is created by making a glass frit seal between the MEMS wafer and a cap wafer. The approach is similar to the long-established use of glass frit as a seal in conventional hermetic ceramic packages. The difference is that now the glass frit forms as well as seals the cavity walls between a cap wafer and a device wafer.

The cap wafer may be stenciled with a mixture of glass and binder, patterned to be the walls of each device cavity. Firing the stenciled wafer sinters the stenciled glass onto the cap wafer, forming the cavity walls. In assembly, the glass cap wafer is aligned and thermo-compression bonded to the device wafer, with the glass frit making the hermetic seal. The glass frit seal accommodates raised metal traces passing under the seal, and may be sealed in vacuum or in a controlled atmosphere. A similar glass-frit cavity package with a controlled atmosphere is available for RF MEMS switches. Limitations on extending the fit-seal approach to more challenging applications include the large size and footprint required for a reliable glass frit seal, and the relatively high processing temperature.

In one implementation, the cap cavities are evacuated though a vent opening, which is closed by the final solder reflow sealing process. The seal ring solder of each die is indented to provide cavity venting for evacuation before sealing. Reflow of the evacuated assembly closes the vent with a hermetic solder seal. The sealed cavity package described above is a near-hermetic modification of this process.

The process flow includes depositing an under-bump metal (UBM) on both the die and cap wafers before plating the solder for the seal ring. The wafers are plasma treated to permit later fluxless reflow soldering. Assembly is cap on wafer. The cap wafer is diced, and the cap chips are aligned and thermo-compression tack-bonded to the die wafer. The tack bonding holds the caps in alignment during their transfer to the reflow chamber. All of the assemblies are simultaneously reflowed in a vacuum chamber, hermetically solder sealing the evacuated cavities.

Other techniques used for wafer-on-wafer sealing include anodic, fusion and covalent bonding. High processing temperatures generally limit the applicability of anodic and fusion bonding. In covalent bonding, clean planarized wafers brought into close contact form covalent bonds. Device and cap wafers are planarized and put through a series of surface conditioning treatments. When the treated surfaces are brought into intimate contact, covalent bonds are created, forming a hermetic seal. This particular process applies only to silicon wafers and related materials, such as silicon oxide (SiO₂) and silicon nitride (Si₃N₄).

### Thin Film Shield

As disclosed herein, one implementation provides an electromechanical device that is protected with a metal thin film shield. In one implementation, a multilayer thin film structure is used to seal the electromechanical device, wherein at least one of the layers is a metal layer. For example, a metal thin film shield can be mated over an oxide TF-cap to encapsulate and prevent degradation due to wafer thinning, dicing and package assembly induced stresses, thus strengthening the survivability of the electromechanical device in the encapsulated cavity. In one implementation, the metal layer is between about 1 and 25 microns thick. In another implementation, the metal layer is between about 5 and 10 microns thick. In another implementation, the metal layer is between about 7 and 10 microns thick. The metal thin film can be at about 8 microns (¼ oz), 12 microns (⅓ oz), 18 microns (½ oz), and 35 microns (1 oz). The distance between metal thin film and MEMS electrodes can be about 6 to 10 microns to reduce effects of coupling capacitance, if any.

In one implementation, the metal thin film is manufactured on the electromechanical system device as part of a redistribution layer (RDL). Adding an RDL allows the device to have distributed power and ground contacts. Redistributed layer and pads also transform off-chip connections from chip scale to board scale, as an alternative to expensive multilayer substrates. Wafer-level-chip scale packages often redistribute to ball-grid array grids as their final external package connection. Redistribution results from adding another conductive layer over the wafer surface, patterned and metalized to provide new bond pads at new locations. This layer is electrically isolated from the wafer except for connections at the original bond pads or to metal runs.

In one implementation, a thin film metal layer, such as a copper layer, is formed at each zone where a TF-cap exists to protect an electromechanical system device. In one implementation, the thin film metal layer is at either a tensile or compression state to help protect the structure from downward pressure from the external environment into the device package.

Thus, in one implementation a varactor device is manufactured according to conventional techniques, but following addition of the upper thin film cap, a second metal layer is deposited over the cap. The upper metal thin film cap may cover a single electromechanical device, or a plurality of devices on a substrate. For example, in one implementation, the metal thin film cap is deposited over two, three or more varactors that are adjacent one another on a substrate.

In another implementation, the thin film metal layer may be made of a thermally conductive material, such as a metal or alloy. The thermally conductive material may help transfer heat from within the electromechanical device to outside the electromechanical device. Additional, the thermally conductive material may be used to spread heat throughout the device to balance the thermal load on the electromechanical device.

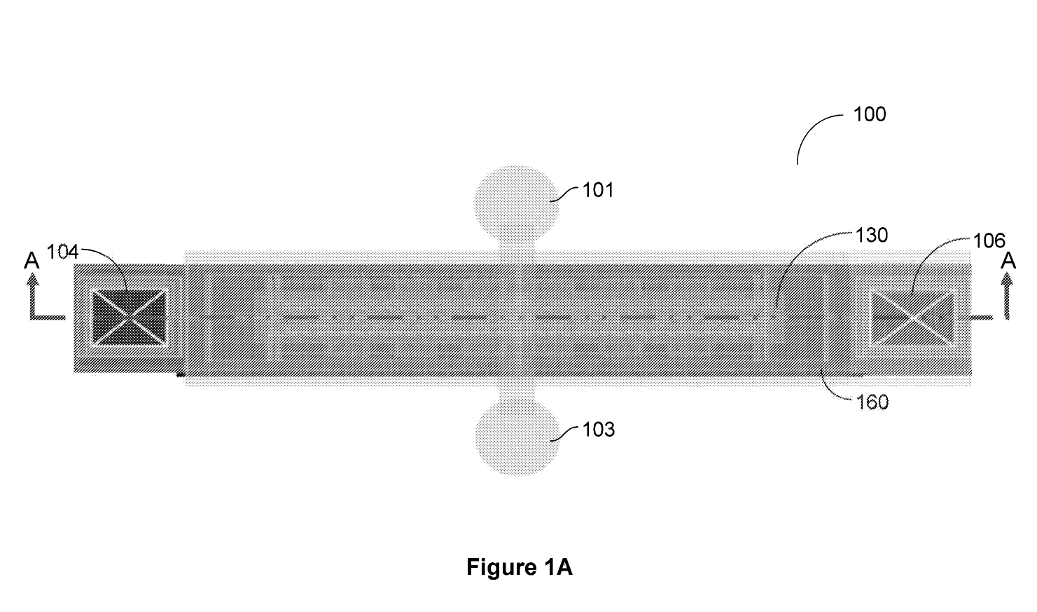

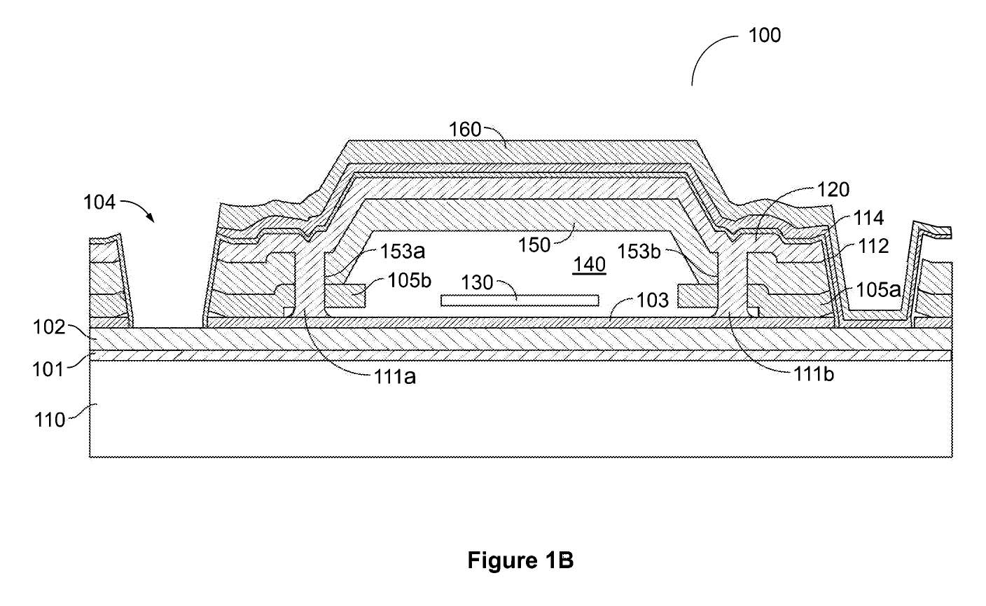

FIG. 1A illustrates a top view of a varactor 100 having a first terminal pad 101 and a second terminal pad 103. Within the varactor 100 is a movable beam 130 that moves within the varactor 100 in response to voltages applied to the terminal pads 101 and 103. As shown, a metal thin film shield 160 is disposed on the top of the varactor 100, and will be explained more fully with reference to FIG. 1B. While the illustrated implementation is a varactor, one of ordinary skill in the art will appreciate that any similar electronic component could be fabricated with the metal thin film as described herein. In other implementations, the MEMS device may be an accelerometer, a resonator, an interferometric modulator (IMOD), or any MEMS device in a cavity that requires encapsulation and wafer-level processing.

FIG. 1B illustrates a cross section view of the device of FIG. 1A taken across the line marked A-A in FIG. 1A. The substrate 110 provides support to an electronic device, such as the varactor 100. The substrate may be made of any material that can support the varactor 100, including glass, plastic, silicon, or other composites or compositions known to those of ordinary skill in the art.

In accordance with the implementation shown in FIG. 1B, a metal trace layer 102 is deposited on top of the substrate 110. As shown, the metal trace layer 102 can provide an electrical connection at a first well 104 (also illustrated in FIG. 1A) to allow electrical connections to the metal trace layer 102. It should be noted that at second well 106 (also illustrated in FIG. 1A), there are additional layers deposited over the metal trace layer 102, thus preventing an electrical connection in that opening. By varying the deposition and masking of the additional layers of the varactor 100, a user can choose whether or not to allow any particular varactor to have an electrical connection to the metal trace layer 102 at the wells 104 and 106. The metal trace layer 102 may be made of any conductive metal, or material such as copper or aluminum, or alloys that include a plurality of conductive metals.

Layered above the metal trace layer 102 is a silicon oxide (SiO₂) layer 103. In one implementation, the SiO₂ layer 103 has a thickness of about 0.05 μm. The SiO₂ layer 103 can be deposited on the metal trace layer 102 to protect additional layers from contacting the charged metal trace layer 102. A second SiO₂ layer 105a-b of about 1.0 μm is then formed on the SiO₂ layer 103. In addition, supports 111a-b are formed on the SiO₂ layer 103 to create cavity 140 within the varactor 100. Supporting the cavity 140 is shell 150 which is deposited on SiO₂ layer 105a-b. The cavity 140 can be formed by release of a sacrificial layer using a releasing agent, such as xenon difluoride (XeFl₂), or another well-known technology for creating cavities within MEMS devices. Also shown within the cavity 140 is a suspended beam 130 which results from the removal of a sacrificial layer that is built up below the beam and thereafter removed through the addition of a releasing agent. Suspended beam 130 may also be referred to as a MEMS component, or a beam.

As shown, the supports 111a-b connect to the shell 150 and help the shell 150 maintain its position above the suspended beam 130. As shown in FIG. 1B, the supports 111a-b may be formed from the same material and layer as the thin film cap (TF-cap) 120.

As discussed above, a TF-cap or superstructure 120 is deposited over the substrate 110 and provides a means for encapsulating the suspended beam 130 within the varactor 100. The TF-cap 120 protects the suspended beam 130 from harmful elements in the environment. The gap or cavity 140 formed between the shell 150 and suspended beam 130 provides room for the movable beam 130 to vibrate within the cavity 140.

However, as discussed above, the TF-cap 120 may not be strong enough to protect the device from manufacturing damage and thus may leave the MEMS package vulnerable to physical and environmental damage.

In the illustrated implementation, additional layers of protection are added above the TF-cap 120 in order to finalize the wafer level packaging. In one implementation, the varactor undergoes a Redistribution Layer (RDL) process following formation of the TF-cap. Redistribution Layer and Bump technology are useful in depositing a thin-film metal routing and interconnection system to each device on the wafer. In this case, it would be used to connect the varactor to the other components of the wafer. This is achieved using the same standard photolithography and thin film deposition techniques employed in the device fabrication itself. Accordingly, during the RDL process, a passivation layer 112 and a seed layer 114 are deposited over the TF-cap 120.

As shown, in this implementation, the metal thin film shield 160 is added over the RDL layer components and TF-cap 120, to provide further protection. The metal thin film shield 160 can extend to the second well 106 so that, for example an underbump metal pad can be used within the well 106 to allow the metal thin film shield to be connected to ground to prevent it from electrically floating. The metal thin film shield 160 is much stronger than oxide TF-cap 120 in terms of yield strength and has a better resistance to fracture and fatigue. The metal thin film shield 160 over TF-cap 120 can also diffuse electrostatic discharge (ESD), reducing incidents of stiction.

A method of packaging a MEMS device according to the implementation shown in FIGS. 1A and 1B will be discussed in more detail below. The packages and packaging methods described herein may be used for packaging any electromechanical device, including, but not limited to, the MEMS devices described above.

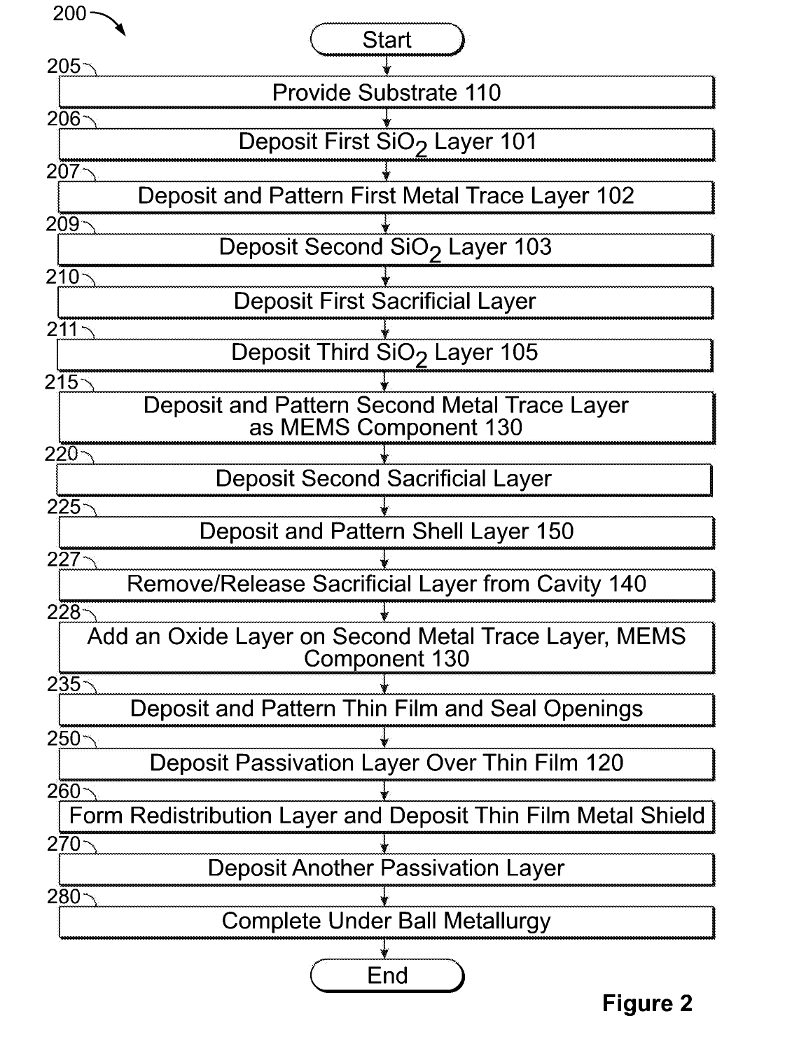

FIG. 2 shows one implementation of a method 200 of packaging the varactor 100 illustrated in FIGS. 1A and 1B, according to the system and methods described herein. At block 205, the substrate 110 is first provided. As previously indicated, the substrate 110 may be any substance capable of having MEMS devices built upon it. Such substances include, but are not limited to, glass, plastic, and polymers.

At block 206, a first SiO₂ layer is deposited. At block 207, a metal trace layer 102 is deposited and patterned on top of substrate 110. As illustrated in FIG. 1B, the metal trace layer 102 extends along the length of the substrate. At block 209, a second silicon oxide (SiO₂) layer 103 is provided over the metal trace layer 102. In one implementation, the SiO₂ layer has a thickness of about 0.5 μm. At block 210, a first sacrificial layer is deposited.

At block 211, a third SiO₂ layer 105a-b may also be deposited over the second SiO₂ layer 103. In one implementation, this third SiO₂ 105a-b layer is about 1 μm. Depending on the deposition and masking of the layers deposited on the metal trace layer 102, the electrical connection between the metal trace layer 120 and any particular varactor can be provided or terminated. For example, in this implementation, the second SiO₂ layer 103 extends over the metal trace layer 102 and over second well 106, effecting prevention of an electrical connection at well 106. However, the connection at first well 104 is open (e.g. no SiO₂ layer on top of the metal trace layer 102) and thus an electrical connection can be provided at first well 104. Further depending on the deposition and masking of this third SiO₂ 105a-b layer, the supports 111a and 111b are later formed, as described below, on the second SiO₂ layer 103 from the deposition of the cap 120.

At block 215, the suspended beam 130 is formed on the substrate 110, for example, via a second metal trace layer. In some implementations, the beam 130 is a MEMS component (e.g., a varactor of a general type), such as the device illustrated in FIGS. 1A and 1B. The beam 130 can be created by using a sacrificial layer to build up the area below the beam 130, as in block 210, and thereafter be removed through the addition of a releasing agent. This method thereby allows the beam to be suspended within the cavity 140.

Moving to block 220, after the suspended beam 130 has been formed above the substrate 110, a second sacrificial layer is deposited over the surfaces of the beam 130 and the substrate 110. As is further explained below, the second sacrificial layer is later removed to form the cavity 140 and thus the second sacrificial layer is not shown in the resulting final varactor 100 illustrated in FIG. 1B. The formation of the second sacrificial layer over the MEMS component may include deposition of a xenon difluoride (XeF₂)-etchable material, dry or wet, such as molybdenum (Mo) or amorphous silicon (Si), in a thickness selected to provide, after subsequent removal, the gap or cavity 140 (see also FIG. 1B) having a desired design size. Deposition of the second sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating. The sacrificial layer can be patterned, using standard photolithographic techniques. This patterning process may localize the sacrificial layer to the MEMS component 130, exposing the substrate 110 around the periphery of the MEMS component 130.

At block 225, a passivation layer, or shell 150 is provided over the sacrificial layer (not shown) and part of the layers 105a-b. The passivation layer or shell 150 may be a moisture barrier, may have a thickness and refractive index that allows it to function as an additional layer of protection to the MEMS component 130, below, an anti-reflective coating, or may function as both a moisture barrier and an anti-reflective coating. As shown, the shell 150 and layers 105a-b are patterned to include orifices 153a-b that allow an etchant to be introduced into the cavity 140 to release the sacrificial layer. In other implementations, the shell 150 may be patterned with other features. For example, the passivation layer 150 may cap only certain features, or may otherwise be patterned to expose underlying materials, such as conductive materials.

It should be realized that the shell 150 may be patterned and etched in a variety of ways to form at least one opening therein through which a release material, such as XeF₂, may be introduced into the interior of the package structure to release the sacrificial layer. The number and size of these openings depend on the desired rate of release of the sacrificial layer. The openings may be positioned anywhere in the shell 150.

At block 227, the sacrificial layer and any sacrificial layers within the MEMS component 130 are released or removed, leaving a cavity 140 between the MEMS component 130 and the shell 150, completing processing of the MEMS component 130. In one implementation, the cavity 140 may be formed by exposing the sacrificial material to an etchant. For example, an etchable sacrificial material such as Mo or amorphous Si may be removed by dry chemical etching, e.g., by exposing the sacrificial layer to a gaseous or vaporous etchant, such as vapors derived from solid XeF₂ for a period of time that is effective to remove the desired amount of material, typically selectively removed relative to the structures surrounding the cavity 140. Other etching techniques, e.g., wet etching and/or plasma etching, also may be used. After removal of the sacrificial material, the resulting fully or partially fabricated varactor may be referred to herein as a “released” varactor. At block 228, an oxide later is deposited over the second metal trace layer, e.g., the MEMS device structure.

In one implementation, as previously described, the sacrificial layer is removed through openings in the shell 150 before the thin film cap 120 is provided. Such openings in the shell 150 are created by etching an opening in the shell 150. XeF₂ reacts with the sacrificial layer to remove it, leaving a cavity 140 between the MEMS component 130 and the shell 150. A sacrificial layer formed of spin-on glass or oxide is gas etched or vapor phase etched to remove the sacrificial layer after the shell 150 has been deposited. A person having ordinary skill in the art will appreciate that the removal process will depend on the material of the sacrificial layer.

At block 235, after the passivation layer, or shell, 150 is provided and patterned, and the sacrificial layer has been released, the thin film cap 120 is then deposited over the entire shell 150. Supports 111a and 111b are formed on the SiO₂ layer 103 from the deposition of the thin film cap 120 as it flows through the orifices 153a-b to create the cavity 140, in conjunction with shell 150, which will protect the MEMS device 130. Further, deposition of the thin film cap 120 can seal the opening(s) in the shell 150. In one implementation, the openings in the shell 150 are sealed by the thin film cap 120. In another implementation, epoxy is used to seal these openings. A person having ordinary skill in the art will appreciate that, depending on the size of the holes, other materials may be used as well, such as materials having high viscosity.

In some implementations, the thin film cap 120 may be any type of material that is hermetic or hydrophobic, including, but not limited to, nickel, aluminum, and other types of metals and foils. The thin film cap 120 may also be formed of an insulator, including, but not limited to, silicon dioxide, aluminum oxide, or nitrides.

The thin film cap 120 can be deposited by chemical vapor deposition (CVD) or other suitable deposition techniques to a thickness of about 1 μm. A person having ordinary skill in the art will understand that the thickness of the thin film cap 120 may depend on the particular material properties of the material selected for the thin film cap 120.

The thin film cap 120 may be either transparent or opaque. A person having ordinary skill in the art will appreciate that transparent materials, such as spin-on glass, may be used to form the thin film cap 120 as they may have material properties that are suitable for use as a thin film cap 120 for protection of the MEMS component 130. For example, a material such as spin-on glass, which is transparent, may provide more strength and protection to the MEMS component 130 within the package structure 100.

The thin film cap 120 is then patterned using photolithographic techniques. This patterning step may also provide features in the thin film 120 that enable the subsequent removal of any remaining sacrificial layer. It should be noted that, at this point in the process, additional sacrificial layers may or may not remain within the MEMS device structure. The patterning at block 223 allows for removal of any sacrificial layers remaining within the MEMS component 130 itself.

At block 250, another passivation layer is deposited. The thin film cap 120 may be too thin and fragile to be employed as a free standing structure. The passivation layer 112, e.g., a dielectric material, may be deposited on top of the thin film cap 120 to enhance its structural stability, as depicted in FIGS. 1A and 1B. The coating may be deposited by deposition techniques, such as chemical vapor deposition (CVD) and sputtering. The coating is then cured and baked. In other implementations, this coating may be formed of other suitable materials (any examples?). In one implementation, a low temperature deposition process is employed, e.g., RF sputter from a ceramic target or reactive sputtering from a silicon target. Overall thickness of the thin film cap 120 and the passivation layer 112 is from about 2000 Å to about 10000 Å. The passivation layer 112 and thin film cap 120 may be patterned with etch holes and vents positioned so that the etchant can permeate the structure and remove sacrificial layers that may still reside within the device. This layer further protects the MEMS component 130 below.

At block 260, a metal thin film shield 160 is deposited via a redistribution layer (RDL) process. As mentioned above, RDL process is used to deposit a thin film metal routing and interconnection system for connection to each dice on the wafer. In one implementation, the metal thin film deposited during the RDL process is used to route signals from certain pads of the circuit board. It can also be used to redistribute the signal. In one implementation, the metal thin film deposited during the RDL process is passive. In yet another implementation, it can be used as a ground to diffuse electrostatic discharge and reduce incidents of stiction.

During the RDL process, the metal thin film shield 160 is deposited over the thin film cap 120. The metal thin film shield 160 may be made of copper and may have a thickness of about 5 to 10 microns. The metal thin film shield 160 provides additional strength and stiffness to the thin film cap 120. In certain implementations where the opening(s) in the thin film cap 120 are sufficiently small (e.g., less than 1 μm), the metal thin film 160 may also be used to seal the openings rather than having another layer of the thin film cap 120, as described above.

The metal thin film 160 may add also another conductive layer over the wafer surface, patterned and metalized to provide new bond pads at new locations. This layer is electrically isolated from the wafer, except for connections at the original bond pads at wells 104 and 106 or to metal runs. In one implementation, copper is used for its superior mechanical signally properties. The use of copper also allows for a thicker layer. In other implementations, nickel can be used.

Forming the RDL layer includes depositing and patterning a protective seed layer 114 over the passivation layer 112. In one implementation, the seed layer 114 is deposited by sputtering. The seed layer 114 can be patterned by depositing and lithographically patterning a photoresist layer over the protective seed layer 114. The protective seed layer 114 can be formed from Ti, TiW, Cr or other materials having similar characteristics.

A metal thin film shield 160 is now deposited over the protective seed layer 114. As previously stated, the redistribution layer may include a conductive line. The metal thin film shield 160 is typically formed from copper (Cu). The metal thin shield 160 extends over the package, and can further extend through the under metal bump 180 area, for example, at well 106 in FIG. 1B. In this way, the thin metal shield 160 allows greater control of the electrical connection between devices.

Next, the redistribution layer is patterned. The redistribution layer can be patterned by depositing and lithographically patterning a photoresist layer over the redistribution layer. The protective seed layer 114 is then etched. As previously mentioned, the protective seed layer 114 is generally formed from polyimide. Alternatively, the protective seed layer 114 is formed by depositing a layer of photosensitive polyimide which is subsequently photolithographically patterned.

The electrical conductor layer in the implementation of FIGS. 1A and 1B may be copper (Cu), as copper has better electrical qualities when used as an electrical conductor layer. Cu for example, is not impervious to corrosion, can be plated at room temperature at the wafer level, and may be sealed during the formation of the redistribution layer and the under bump material structure.

Advancing to block 270, another passivation layer, using the same methods as previously described, is added as above at block 223, for added protection.

Blocks 250 to 270 can be repeated for added benefits.

At block 280, under bump metallurgy (“UBM”) is completed. The under bump material structure is formed over at least one conductive line. The under bump metal structure includes a solder wetable metal layer formed over the redistribution layer, and a second metallic protective layer for receiving the solder bump.

Solder may then be deposited on the under bump material structure where solder bump are to be formed. The solder can be deposited by electroplating, evaporation or by printing a solder paste. These techniques of depositing solder are well known in the art of semiconductor processing.

In one implementation, the method of packaging a MEMS device according to this implementation integrates the sealing of the package structure 100 into the front-end processing and eliminates the need for a separate backplane, desiccant, and seal, thereby lowering the cost of packaging. In another implementation, the metal thin film shield 160 reduces the amount of desiccant required rather than eliminating the need for a desiccant.

An added benefit is achieved in that no extra costs may be required to carry out the method described herein, because metal thin film cap by RDL is a part of standard wafer-level chip scale package steps for routing signals to and from various bond pads on a circuit board. Packaging in accordance with these implementations reduces the material constraints with respect to both the desiccant and seal, thus allowing a greater choice of materials, geometries, and opportunities to reduce costs. The metal thin film shield 160 can further reduce hermetic requirements to allow for not only elimination of a backplane but also allows any additional moisture barrier requirements to be incorporated into the module level packaging. It is generally desirable to keep the package structure as thin as possible and the package structure 100 shown in FIGS. 1A and 1B provides for a thin structure.

The system and method described herein has applicability outside of MEMS devices. For example, because of the added strength and protection afforded by the metal thin film, it can be applied over bigger and more expensive dies, and can be used with CMOS and other devices that require protection from movement and/or moisture. This is especially important when investing in larger, more expensive dies, because handling equipment can cause damage that isn't immediately known. In such instances, the damage to the device may not be discovered until a point much later in the manufacturing or device placement process itself.

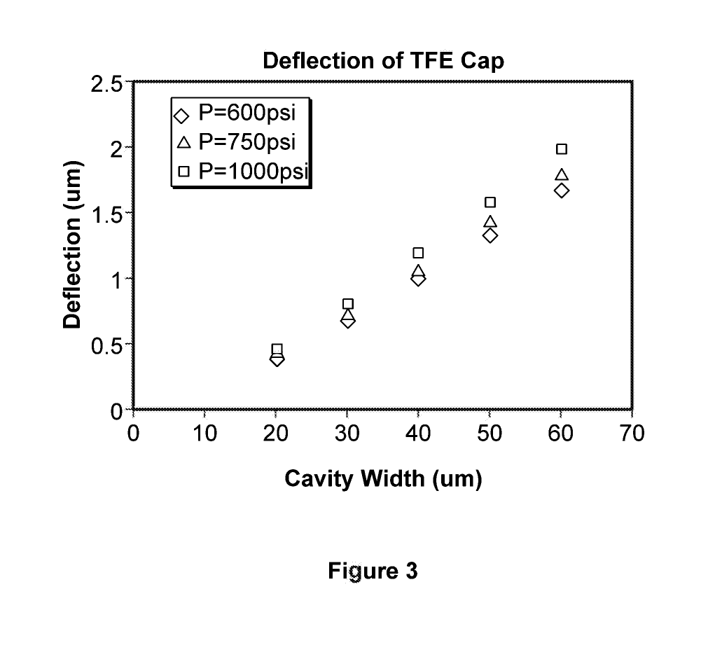

FIG. 3 shows deflection of the TF-cap at various pressures. As shown in the table, pressure reaching about 750-1000 psi can be expected during the transfer molding process. As the size of the cavity grows, more bend can occur in the film. The metal thin film shield protects the underlying TF-cap and can withstand more pressure during the transfer molding process and also is more elastic, so it will not easily break.

### EXAMPLE 1

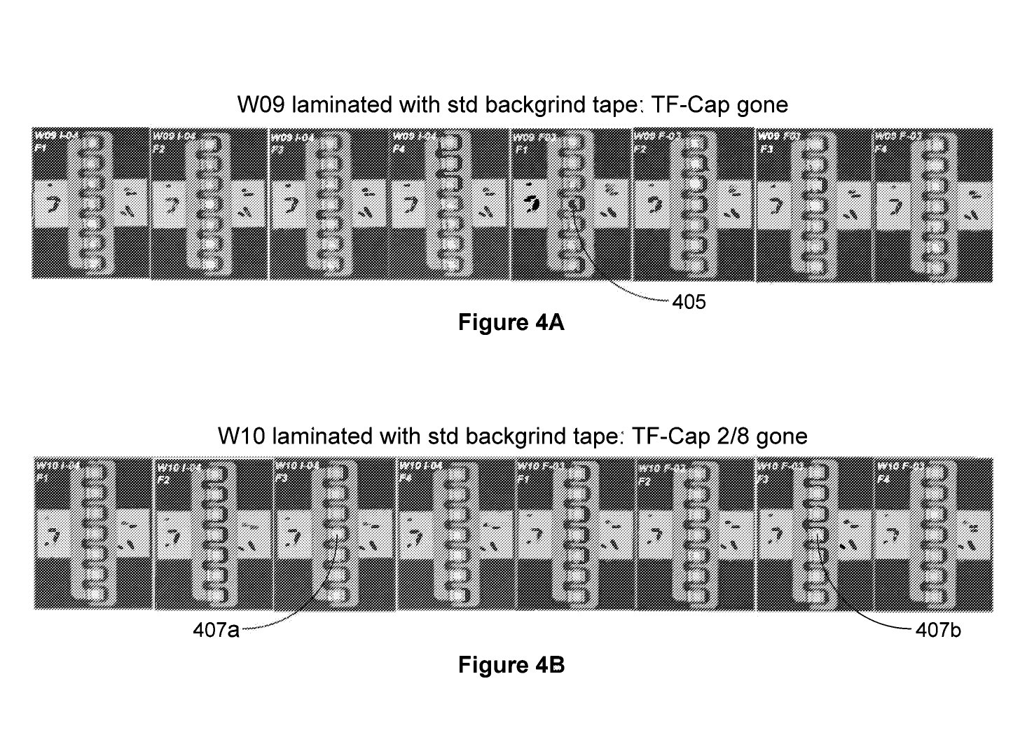

In order to thin the wafers, they are applied face down on a sticky tape, to hold them in place, as shown in FIGS. 4A and 4B. Experiments were done using both W09 laminated with standard backgrind tape conditions and also W10 laminated with UV backgrind tape. In both cases, the thin film cap was dislodged or torn away during the process because the strength of the thin film was not protective enough over the stickiness of the tape during the movement of the wafer thinning process. For example, test number W09 F03 F1 405 and 407a and 407b show that the middle element has been damaged and/or torn away.

### EXAMPLE 2

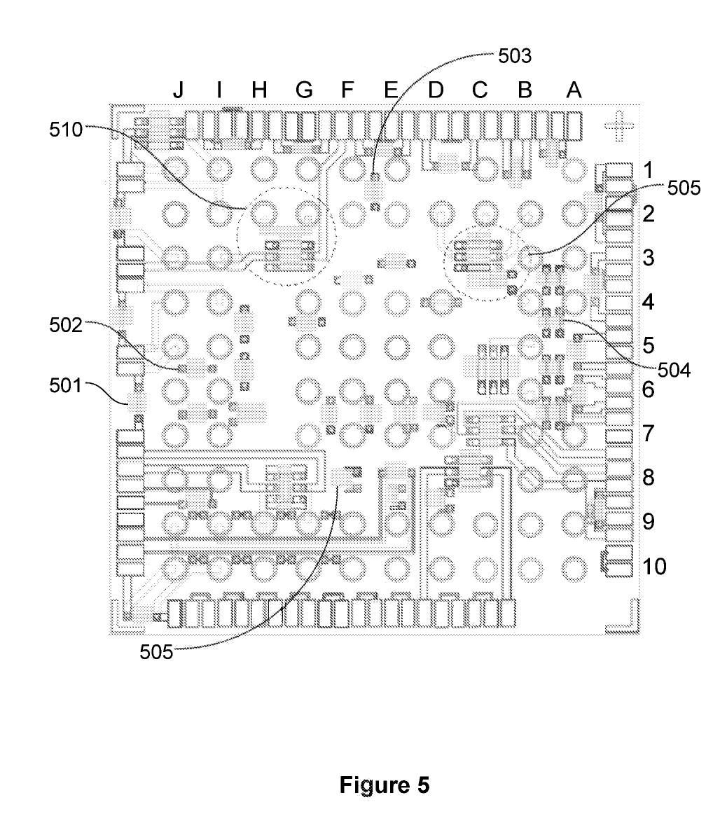

FIG. 5 is an example of a 5 mm×5 mm die for a package with forty-two MEMS components, a sampling of which are indicated as 501-505. In this implementation, an oxide film cap, or TF-cap is formed to enclose each open cavity for each of the forty-two MEMS components. FIG. 5 illustrates an example of a metal thin film shield 160 for WLCSP. As shown at 505, one single metal thin film shield 160 can cover multiple TF-caps 120 and MEMS 130 beneath. The integrity of each metal thin film shield 160 can be monitored by probing its termination pads for changes in metal film (shown at 510) sheet resistance. Changes in sheet resistance may be characterized and correlated to determine whether the metal thin film shield 160 is at a tensile or compression state or possibly damaged.

One drawback of most wafer-level packaging techniques is the requirement for a seal ring. The inclusion of a seal ring and the appropriate bonding pads outside the ring significantly increases the area of an RF MEMS circuit. In such a circuit, there are four areas that need to be considered: the RF MEMS circuit, the seal ring, the interconnect areas, and the saw kerf (the kerf is a region in a wafer designated to be destroyed by chip dicing.). The regions required for the seal ring, interconnect area and the saw kerf increase the final size of the RF circuit, thereby reducing the available number of circuits per wafer. For instance, the glass-frit WLP technique described above typically requires a seal ring and interconnects area of about 0.3-0.7 mm per side. The difference in realized circuits per wafer is substantial. One advantage of the system and method disclosed herein is that unlike encapsulating the MEMS device with another wafer, the metal thin film shield does not require a seal ring, and the footprint for each MEMS device is reduced. Eliminating the seal ring area greatly increases the number of available circuits per wafer, which significantly reduces the cost per circuit.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the MEMS device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An electronic package, comprising:
a substrate having an electronic device;
a thin-film cap sealed to said substrate to form a package, wherein said electronic device is inside said package; and
a metal thin film layer deposited adjacent the thin-film cap.

2. The device package of claim 1 wherein the metal thin film comprises one or more layers of copper.

3. The device package of claim 1 where said metal thin film increases the rigidity of the thin film cap.

4. The device package of claim 1 where said metal thin film is about 1 to 25 microns in thickness.

5. The device package of claim 1, where the metal thin film layer is made from a thermally conductive material.

6. The device package of claim 1, where the metal thin film layer extends to an underbump metal pad.

7. The device package of claim 1, wherein the metal thin film is a ground plane.

8. The device package of claim 1, further comprising an additional metal thin film deposited over the metal thin film layer.

9. The device package of claim 1, wherein the electronic device comprises a varactor.

10. The device package of claim 1, wherein the electronic device comprises an accelerometer.

11. The device package of claim 1, wherein the electronic device comprises a microelectromechanical systems (MEMS) device array.

12. The device package of claim 1, wherein the metal thin film provides a hermetic barrier.

13. A method of manufacturing an electronic device, comprising:
providing a substrate having an electronic device and encapsulated by a thin-film cap; and
applying a metal thin film over said thin-film cap.

14. The method of claim 13, wherein the metal thin film is applied during a redistribution layer process.

15. The method of claim 13, wherein the metal thin film includes copper.

16. The method of claim 13, wherein the metal thin film is passive.

17. The method of claim 13, further comprising applying an additional metal thin film.

18. The method of claim 13, wherein the electronic device is a varactor.

19. The method of claim 13, further comprising providing a passivation layer over the thin film cap before applying the metal thin film.

20. An electronic device package, comprising:
a substrate having an electromechanical device;
a thin film cap deposited above the electromechanical device and configured to encapsulate the electronic device into a package; and
means for reinforcing the thin film cap.

21. The device package of claim 20, wherein the electromechanical device is a varactor.

22. The device package of claim 20, wherein the means for reinforcing has at least one metal thin film formed over the thin film cap.

23. The device package of claim 22, wherein the at least one metal thin film extends to a metal pad.

24. The device package of claim 20, wherein the electromechanical device is a microelectromechanical system (MEMS) device.

25. The device package of claim 20, wherein the means for reinforcing comprises one or more layers of copper.
